(19) United States
(12) Patent Application Publication
(10) Pub. No.: US 2017/0362682 A1
(43) Pub. Date: Dec. 21, 2017

(54) Method For Recycling Waste Electrical And Electronic Equipment

(71) Applicants: BRGM, Orleans Cedex 2 (FR); Centre National de la Recherche Scientifique (CNRS), Paris Cedex 16 (FR); Universite d'Orleans, Orleans Cedex 2 (FR)

(72) Inventors: Nour-Eddine Menad, Orleans (FR); Sylvain Guignot, Orleans (FR); Iskender Gokalp, Orleans (FR); Stéphane Bostyn, Lailly-en-Val (FR); Yann Graz, Orleans (FR); Jacques Poirier, Saint Privé-saint Mesmin (FR)

(21) Appl. No.: 15/539,570

(22) PCT Filed: Dec. 18, 2015
(86) PCT No.: PCT/FR2015/053635

§ 371 Date: Jun. 23, 2017

(30) Foreign Application Priority Data
Dec. 23, 2014 (FR) 1463195

(51) Int. Cl. C22B 15/00; H05K 3/22; B09B 3/00

(52) U.S. Cl. CPC C22B 15/0056; B09B 3/0083; H05K 3/22; B09B 3/0016; H05K 2203/0228; H05K 2203/104; H05K 2203/1105; H05K 2203/178; H05K 2203/0796

(57) ABSTRACT

The method for separation of metals from electronic cards includes a step of processing the electronic cards in an aqueous medium under supercritical conditions. The method also a later step of crushing solid materials coming from the treatment under supercritical conditions.

### FIELD OF THE INVENTION

The invention relates to a process for recycling the metals contained in the electronic boards of waste electrical and electronic equipment (W3E or WEEE).

### BACKGROUND OF THE INVENTION

An electronic board is a printed circuit onto which various types of electronic components are welded. These boards are found in a lot of electrical and electronic equipment (EEE) such as cell phones, printers or else computers. They are generally composed of 35% of generic and precious metals, 35% of glass fibers (or siliceous fibers) constituting the reinforcement of the board, and of 30% of organic materials such as plastics and resins. In terms of precious metals it is possible therein to find gold in processors and on the connections, palladium in multilayer ceramic capacitors (MLCC) and some transistors, tantalum in certain capacitors and silver in integrated circuits.

Table 1 shows examples of the compositions of cell phones, personal computers (PCs) and their impact on the annual metal demand (UNEP 2013).

TABLE 1

| | | Urban mines |
|---|---|---|
| | | (a + b) |
| Cell phones (a) | PCs & laptops (b) | Mining production |
| 1600 million units/year | 350 million units/year | Share |
| ×250 mg Ag ≈ 400 t | ×1000 mg Ag ≈ 350 t | Ag: 22200 t/yr 3% |
| ×24 mg Au ≈ 38 t | ×220 mg Au ≈ 77 t | Au: 2500 t/yr 5% |
| ×9 mg Pd ≈ 14 t | ×80 mg Pd ≈ 28 t | Pd: 200 t/yr 21% |
| ×9 g Cu ≈ 14000 t | ×~500 g Cu ≈ 175000 t | Cu: 16 Mt/yr 1% |

The global sale volumes of these devices suggest that they contain large amounts of metals.

Several metal recycling processes are already known (cf. Delfini et al. 2011. Journal of Environmental Protection. 2, 675-682). Thus, electronic boards derived for the most part from production scrap are treated by hydrometallurgy in order to recycle the gold that they contain. Other electronic boards are treated by pyrolysis in order to eliminate the resin and concentrate the precious metals. The precious metals are then recovered by pyrometallurgical or hydrometallurgical routes. These processes are harmful to the environment since they require the use of organic solvents. Specifically, as regards the pyrolysis treatment, the metals obtained from this process are sooted up and must then be subjected to a hydrometallurgical treatment. Furthermore, the pyrometallurgical treatment requires prior grinding to a fine particle size which is associated with a high energy consumption. This fine grinding is responsible for most of the losses of metals to dust.

Supercritical water may be used alone or in combination with an oxygen-generating species (of hydrogen peroxide type) in order to oxidize the organic material. A fluid is said to be supercritical when it is placed under temperature and pressure conditions beyond its critical point. The temperature and pressure pair of the critical point of water is Tc=374° C., Pc=22.1 MPa. Under these supercritical conditions, water has solvating properties similar to those of a hexane-type organic solvent.

In the case of an H₂O/O₂ mixture, the degree of decomposition of the organic molecules may reach 99.99%, with, as gaseous compounds emitted, CO₂, N₂, excess O₂, or even CO in trace amounts if the temperature of the reaction is below 500° C. Thus, the supercritical water oxidation technique may generate, under appropriate conditions, effluents that are directly compatible with the environment.

At the same time, and due to the decrease in the dielectric constant and in the ionic dissociation constant of water in these temperature and pressure ranges, the solubility of the mineral salts decreases greatly.

The organic material oxidation reaction is exothermic, which makes it possible, for contents of organic material in the effluent of greater than approximately 4 wt %, to have a process that is self-sufficient in terms of heating energy (cf. Moussière et al. 2007. The Journal of Supercritical Fluids. 43, 324-332).

A metal recycling process is known from Xiu et al. (2013. Waste Management. 33, 1251-1257) that comprises a step of treating under supercritical conditions. The solvent used is water, with or without oxidizing agent (hydrogen peroxide). In this process, the treatment under supercritical conditions is carried out on electronic boards previously ground to a particle size of less than 3 mm. The step of treating under supercritical conditions is carried out in a reducing medium or in an oxidizing medium. During this step, the organic material is destroyed and eliminated in the effluents. This step is then followed by a separation of the siliceous fibers by hydrochloric acid.

This prior art process therefore requires a prior step of grinding to a very fine particle size which, like the pyrometallurgical treatment, generates dust and leads to losses of metals. The fine grinding step is also associated with a high energy consumption.

### SUMMARY OF THE INVENTION

The objective of the invention is to propose an alternative process that has none or only some of these drawbacks and that enables an improved recycling of metals present in electronic boards.

For this purpose, one subject of the invention is a process for separating metals from electronic boards, characterized in that it comprises:
a) a step of treating said optionally fragmented electronic boards in an aqueous medium under supercritical conditions of said medium and
b) a subsequent step of crushing the materials in the solid state that are derived from the step of treating under supercritical conditions.

In the process of the invention, the fragmentation of the starting materials, if it is used, is advantageously performed to coarser particle sizes than the conventional treatments. Unlike the teaching of the prior art, this fragmentation of coarser size does not reduce the yield, but increases it by preventing or substantially minimizing the losses due to the creation of dust resulting from the grinding.

The objective of the fragmentation is in particular to obtain fragments of small enough size so that they can be introduced into the reactor in which the treatment under supercritical conditions takes place. Thus, for a treatment in a reactor having a relatively large capacity, it may not be necessary to grind the electronic boards. The process may therefore be used on complete boards. This particular embodiment is therefore advantageous since it does not require a shredding device. It is also faster. In this embodiment, the risk of loss of materials is also reduced because the process does not include, in contrast to the other embodiments, a step of transferring the materials. However, for reactors of smaller capacity, fragmentation may prove necessary.

A “coarse” fragmentation may also be advantageous for enabling easy transport, avoiding the loss of metals in the dust generated and/or for increasing the exchange area between the water and the material and thus accelerating the degradation kinetics, or optimizing the material surface area treated. Thus, the average particle size of the fragments obtained at the end of a fragmentation step may range from 0.5 to 15 cm, preferably from 0.8 to 10 cm and more preferentially still from 1 to 5 cm.

The expression “average particle size” is understood to mean the particle size, that is to say the measurement of the largest dimension represented by at least 60%, preferably at least 75%, more preferably still 90% of the fragments.

These values are determined by screening through screens with meshes suitable for the particle sizes to be measured.

The fragmentation is carried out by shredding or by grinding, for example using a knife mill.

Advantageously, the grinder is equipped with a screen for carrying out the grading of the fragments resulting from the grinding.

In step a) of treating under supercritical conditions, that is to say under conditions where the temperature is above 374° C. while the pressure is greater than 22.1 MPa, the organic material is destroyed and eliminated in the effluents. The resin from the electronic boards is attacked, which releases the siliceous fibers, and also the metals. The products obtained at the end of this step predominantly consist of the metals initially present in the boards. Conversely, the resin forming the material, and composed of plastics and fibers, is largely eliminated by the attack under supercritical conditions. However, fibers and resin may remain attached to the solid portion of the electronic boards. This step of the process generates very few losses of metals. Indeed, the liquid phase contains very few metallic elements and almost all of the metals are recovered in the solid phase of the supercritical water treatment.

Advantageously, the temperature in the medium ranges from 374° C. to 600° C. for a pressure of 22.1 MPa to 30 MPa. Preferentially, the temperature is above 500° C. and preferentially equal to 600±20° C. Indeed, under temperature conditions below 500° C., there may be a release of traces of carbon monoxide.

Advantageously, the supercritical conditions of the aqueous medium are maintained for a duration greater than or equal to 30 minutes and preferably ranging from 60 minutes to 180 minutes.

Optionally, the medium in which the treatment under supercritical conditions is carried out contains oxygen (for example air) or one or more oxygen-generating species, and in particular hydrogen peroxide. The addition of an oxidant improves the reaction. Furthermore, the addition of a catalyst such as an alkali metal (for example Na₂CO₃, KHCO₃, K₂CO₃, KOH, and/or NaOH) and/or activated carbon may also improve the reaction.

Optionally, the treatment is carried out in an autoclave and the supercritical conditions are achieved by increasing the temperature, and preferably exclusively by increasing the temperature.

Advantageously, the process according to the invention comprises a step of recycling the aqueous medium used. The liquid resulting from the reaction under supercritical conditions between the electronic boards and the supercritical fluid used may comprise an oily phase. The various phases of the reaction medium are separated. The oily phase, if there is one, can be separated from the aqueous phase by decantation. The aqueous phase may then be purified by addition of sulfate salts and precipitation of its main pollutant that is generally barium. The liquid phase may then be reused as aqueous medium of the process of the invention, optionally with an addition of hydrogen peroxide at the reactor inlet.

The solid phase may be recovered by filtration.

In step b) of crushing the materials in the solid state that are derived from the step of treating under supercritical conditions, the metals are separated from the fibers which had remained bonded thereto. The separation is based on the difference in ductility of the materials present. Specifically, during the crushing, the ductile metal phases are flattened, whereas the siliceous fibers crumble, leading to a modification of the particle size distribution of the sample. The crumbled portions are referred to as “fines”.

Within the meaning of the invention, “crushing” is understood to mean the action of flattening and deforming a body by a strong compression and/or by a violent impact. The crushing is advantageously carried out by moving the object carrying out the compression against the compressed object.

Advantageously, a pressure ranging from 0.08 to 3 kPa per gram of material treated, and preferentially from 0.1 to 2 kPa per gram is exerted.

Metals and fines may easily be separated by a conventional screening step. This separation technique has the advantage of not requiring prior grinding of the boards and of being associated with a good yield. It does not consume reactant and does not generate effluents. Finally, this separation step makes it possible to recover the siliceous fibers.

Advantageously, the crushing takes place in a crusher which is preferentially a drum screen with heavy elements. The heavy elements may be bars or balls. In general there are at least two thereof. They are made of a material to which the metals and the siliceous fibers do not adhere under the hygrometry, temperature and pressure conditions of step b), such as iron. Their weight is between 50 and 500 g per gram of material treated, and preferentially between 100 and 200 g per gram. The size of the meshes of the screen may vary from 1 to 10 mm, preferably from 2 to 5 mm, and more particularly from 1 to 3 mm (for example around 2 mm).

Preferentially, the crusher has a rotational speed of the order of 20 to 100 rpm, preferably 40 to 80 rpm, and more preferentially still from 50 to 70 rpm.

Due to the fact that the crushing takes place in a screen, the grading (that is to say the separation) of the fines and of the metal particles is carried out directly at the outlet of the crusher.

Advantageously, the crushed materials are treated so as to separate the fragments having a size of less than 3 mm, preferentially less than 2 mm and more preferentially still less than 1 mm.

Preferentially, the crushed materials are subjected to a low-intensity magnetic separation, preferentially under a magnetic field ranging from 200 to 600 gauss, preferentially from 300 to 500 gauss and more preferentially still from 375 to 425 gauss.

Another subject of the invention is the use, for the separation of metals from electronic boards, of means for treating in an aqueous medium under supercritical conditions and crushing means, optionally combined with fragmentation means. This use may be carried out under the conditions and with the means described in the present application.

Another subject of the invention is a device that combines the aforementioned means with the conditions described in the application. For example, it may combine a reactor comprising a supercritical medium with a crusher as described in the present application.

The invention will be better understood on reading the following examples, including figures, which are given solely by way of example.

### BRIEF DESCRIPTION OF THE FIGURES

FIG. 1 depicts the steps of one embodiment of the process for recycling electronic boards according to the invention exemplified in examples 1 to 3.

FIG. 2 presents the crusher used to crush the electronic boards in the implementation examples 1 to 3.

FIG. 3 is a photograph taken with a scanning electron microscope (SEM) representing the morphological appearance of the solid portion obtained after fragmentation according to example 3.

FIGS. 4 to 6 bring together the local qualitative chemical analyses by scanning electron microscopy-energy dispersive spectroscopy (SEM-EDS) carried out on the solid portion obtained at the end of the fragmentation according to example 3, during the SEM visualization thereof.

FIG. 7 is a SEM photograph representing the appearance of the fines obtained at the end of the crushing according to example 3.

FIG. 8 presents a local qualitative chemical analysis carried out by SEM-EDS at a point of the fraction of the fines obtained at the end of the crushing according to example 3.

FIG. 9 presents a table bringing together the images of the products obtained in examples 1 and 2 after attack with supercritical water in the presence of hydrogen peroxide.

### DETAILED DESCRIPTION OF THE INVENTION

### EXAMPLES 1 AND 2

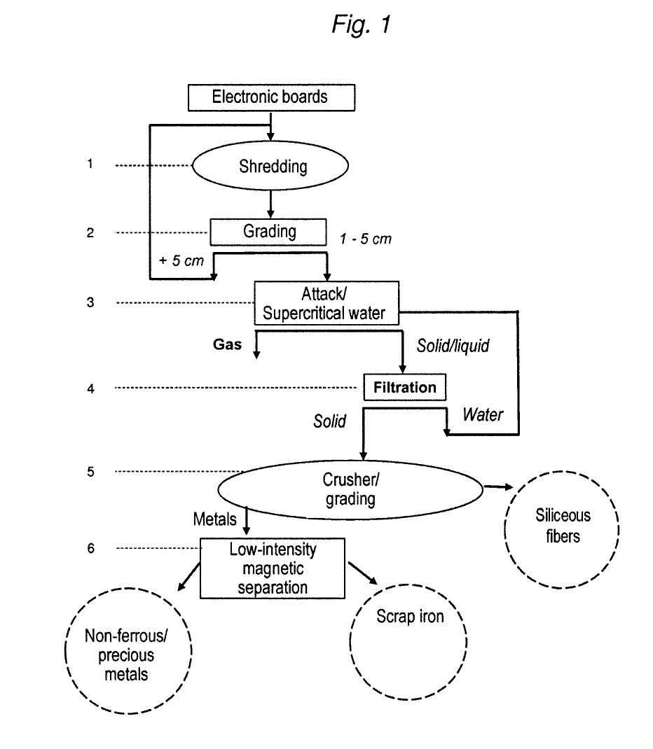

In a first example, laptop computer electronic boards were subjected to a fragmentation using a knife mill equipped with a screen having a 5 cm mesh. This is the (“shredding”) step 1 of the process depicted in FIG. 1. In this example, the objective of the fragmentation was to obtain fragments having a size generally greater than 1 cm and smaller than 5 cm. At the end of the fragmentation, the fragments are subjected to a grading (step 2 of the process depicted in FIG. 1). The fragments having a size greater than 5 cm are again subjected to the shredding step 1. The fragments having a smaller size are subjected to step 3 of the process depicted in FIG. 1. More specifically, 30 g of fragments thus obtained were then introduced into an autoclave having a volume of 300 ml in which they were bought into contact with 30 g of an aqueous solution of hydrogen peroxide having a concentration of 33% by weight. The temperature in the autoclave was raised to 600° C. which made it possible to achieve a pressure of 250 bar. These pressure and temperature conditions were achieved in around 30 minutes. The fragments were then maintained under these conditions for 30 minutes, then the autoclave was depressurized.

The solid phase was then separated from the liquid phase by filtration on filter paper having a porosity of 2.5 μm, so as to recover all of the solid phase (step 4 of the process depicted in FIG. 1).

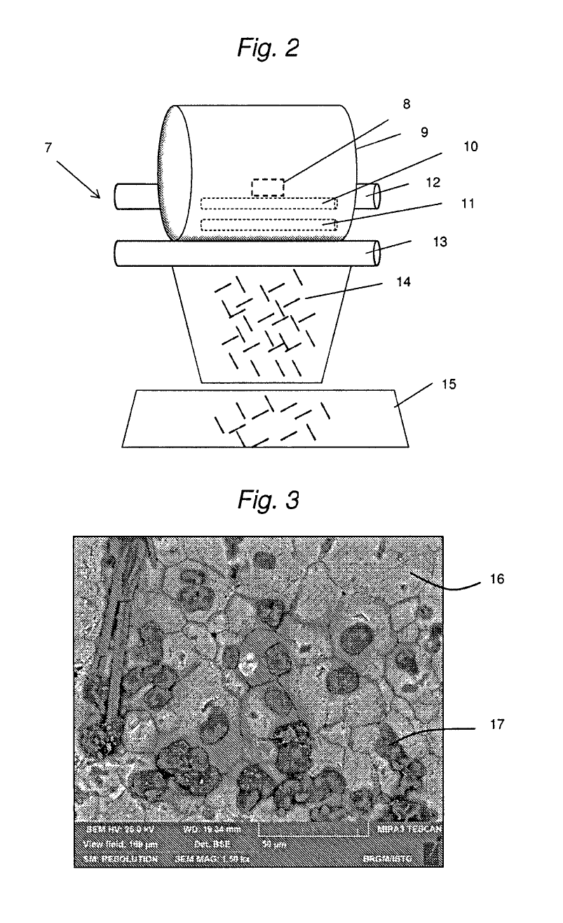

The solid phase was then passed through a crusher represented in FIG. 2, which is an example of the crusher indicated in step 5 of the process depicted in FIG. 1.

FIG. 2 represents a crusher 7 which is a drum screen with heavy elements, also used in examples 1 to 3 as a grader. Solid residues 8 resulting from the attack under supercritical conditions (step 3 of the process) are placed in a rotary screen 9 which has a 2 mm mesh and contains two heavy bars 10 and 11. The heavy bars 10 and 11 are cylinders, each with a length of 15 cm, a diameter of 4 cm and a weight of 1.9 kg. The device is closed and positioned on two bars 12 and 13 positioned outside the screen 9. These bars are rotated, which drives the rotation of the screen, thus ensuring the movement of the heavy bars 10 and 11 and the crushing of the solid residues 8. This crushing releases friable portions 14 of the initial resin which again stick to the solid residues 8. These crumbled portions 14, referred to as “fines”, pass through the openings of the screen and are recovered at the bottom, having a mean particle size of less than 2 mm, in dedicated trays 15. The crushing time was around 3 minutes, at the end of which time there were no longer, visually, any fine particles exiting the screen. The material remaining in the screen is referred to as “solids” and is recovered. The “fines” and the “solids” are then weighed.

The metals thus separated from the resin may then be subjected to a low-intensity magnetic separation, under a magnetic field of 400 gauss. The non-ferrous metals, including the precious metals, were thus separated from the scrap iron.

The process described in example 1 was repeated in another example, example 2, but the duration during which the fragments of electronic boards were maintained under supercritical conditions is 2 hours once the pressure and temperature rise is achieved, and not 30 minutes as in example 1. The crushing time was around 1 minute 30 seconds, at the end of which time there were no longer, visually, any particles exiting the screen.

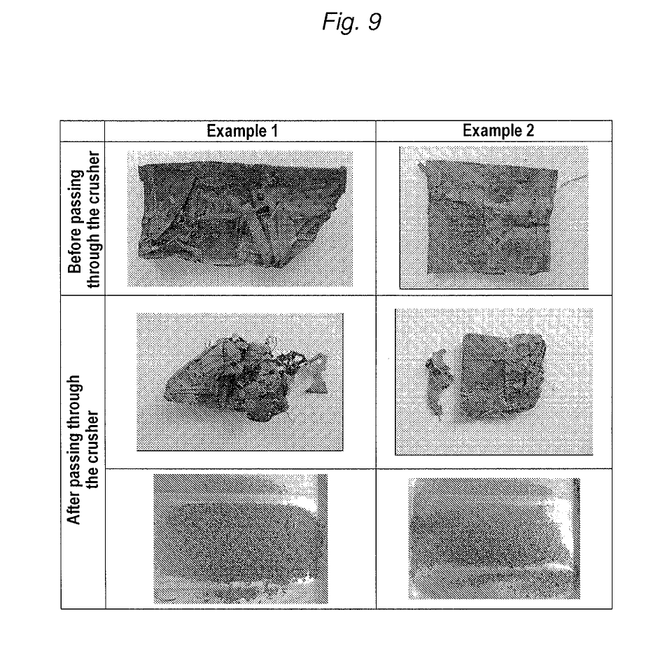

FIG. 9 brings together the images of the products obtained after attack with supercritical water in the presence of hydrogen peroxide of examples 1 and 2.

Table 3 indicates the weights of fines and solids obtained respectively in examples 1 and 2.

TABLE 3

| | Supercritical oxidation 2 h | | Supercritical oxidation 30 min | |
|---|---|---|---|---|
| Fines | 3.91 g | 43.9% | 5.95 g | 51.0% |
| Solids | 5.00 g | 56.1% | 5.72 g | 49.0% |
| TOTAL | 8.91 g | 100% | 11.67 g | 100% |

The appearance of the products before they pass through the bar crusher suggests a better degradation of the resin after two hours of treatment. The smaller percentage of fines for the product obtained after a supercritical oxidation of two hours confirms this observation. Furthermore, the duration of the crushing is also two times shorter.

### EXAMPLE 3

In a third example, a laptop computer electronic board was subjected, as in examples 1 and 2, to shredding using a knife mill equipped with a screen having a 5 cm mesh. The fragments obtained have a mean size of 5 cm.

30 g of the fragments thus prepared were then introduced into an autoclave having a volume of 300 ml in which they were bought into contact with 30 g of water. The temperature in the autoclave was raised to 600° C. which made it possible to achieve a pressure of 250 bar. These pressure and temperature conditions were achieved in around 30 minutes. The fragments were then maintained under these conditions for 60 minutes, then the autoclave was depressurized.

The solid phase was then separated from the liquid phase by filtration on filter paper having a porosity of 2.5 μm, so as to recover all of the solid phase.

The solid phase was then passed through the crusher described in FIG. 2 for a duration of around 1 to 3 minutes, until there were no longer, visually, any particles exiting the screen. The portions thus crumbled were recovered and have a particle size of less than 2 mm.

The metals thus separated from the resin may be subjected to a low-intensity magnetic separation, under a magnetic field of 400 gauss. The non-ferrous metals, including the precious metals, were thus separated from the scrap iron.

FIG. 3 presents an electron microscope image of the solid portion obtained after passing through the crusher represented in FIG. 2. The solid has a light surface (16) of homogeneous appearance and dark deposits (17) on this surface.

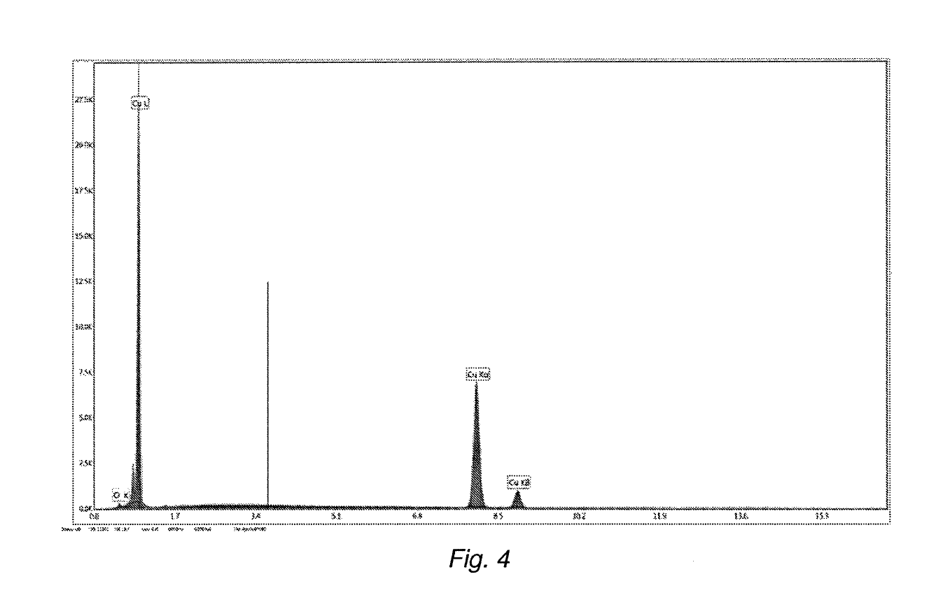

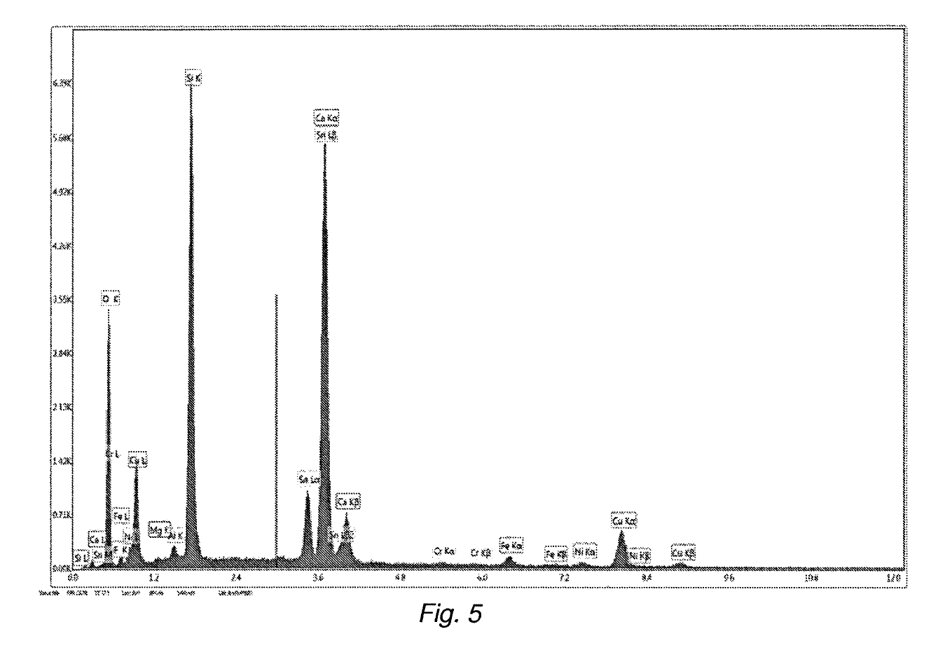

A determination of the local chemical composition was carried out by SEM-EDS in different zones of the board seen in FIG. 3. More specifically, an analysis was carried out on the light zone (16) of the board, and two analyses were carried out on two of the darker zones (17). The results are presented in FIGS. 4 (analysis of the light zone) and 5 and 6 (analysis of the dark zones).

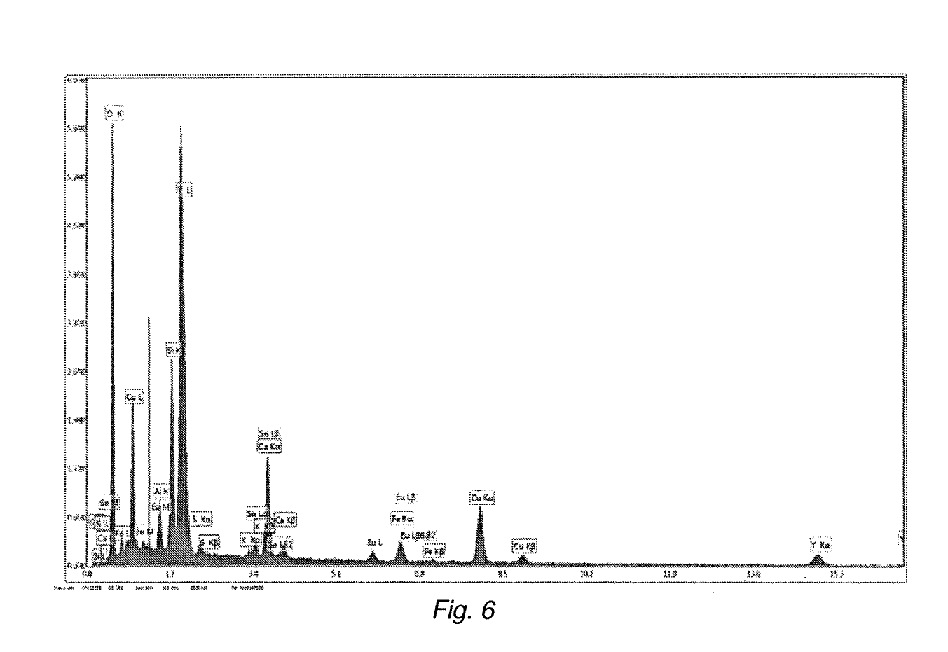

In the SEM-EDS analysis, a stream of electrons bombards the sample and gives rise to an emission of x-ray photons, the energy spectrum of which characterizes the constituent elements of the material to be analyzed. This spectrum is analyzed by a semiconductor detector which produces voltage peaks proportional to the energy of the photons received (principle of Energy Dispersive Spectroscopy, EDS). The voltage peaks obtained make it possible to quantify the elements emitting at a given energy, expressed in kiloelectron volts (keV). By way of example, FIG. 6 shows in particular the emission peak of yttrium, level L (Y L), at around 1.9 keV.

Thus, FIG. 4 shows a zone composed of virtually pure copper metal. Conversely, FIG. 5 and FIG. 6 show little copper but a lot of calcium, tin, europium and yttrium oxides.

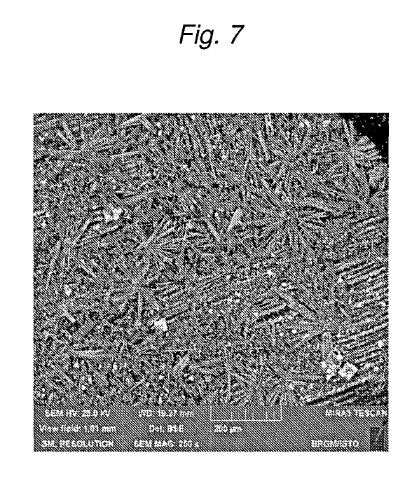

A similar characterization to that carried out for the pure solids was performed on the fines recovered after crushing and constituted of the fibers of the reinforcement of the board. The SEM image (FIG. 7) presents an assembly of acicular particles, that is to say in the form of needles and of homogeneous appearance. Due to the fact that the initial fibers have a needle shape and that the resin has no particular shape, it appears that the fines mainly contain fibers. The supercritical water has therefore mainly attacked the resin of the electronic board and not the fibers.

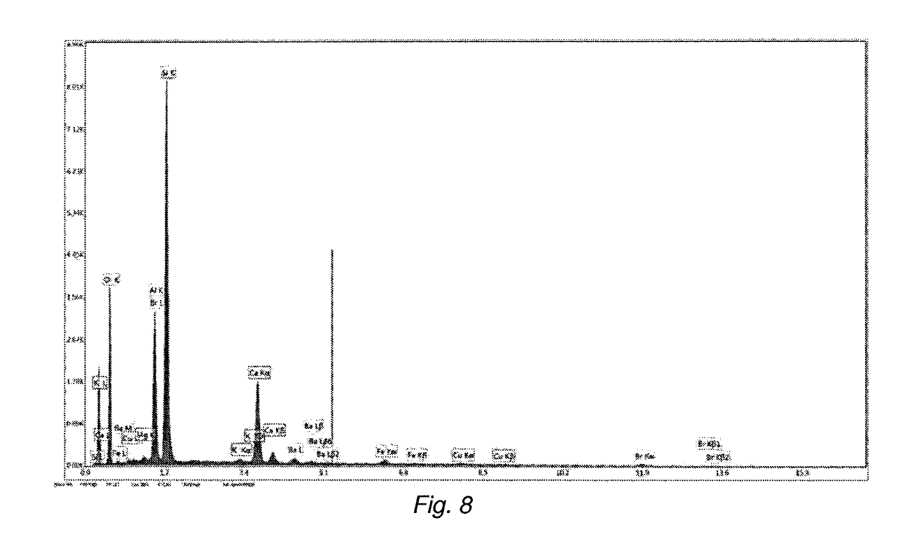

This is confirmed by the results of analysis of the local chemical composition by SEM-EDS (FIG. 8). This analysis makes it possible to identify the glass fibers of the board (silicon, calcium and aluminum oxides, traces of barium). The analysis reveals copper, but in the form of ultra-trace amounts.

Table 4 presents the chemical composition data of the liquid phase at the outlet of the step of attack by supercritical water, after the filtration (step 4 of FIG. 1) of the products of example 1.

TABLE 4

| Elements | Ag | Al | As | Ba | Be | Cd | Co | Cr |
|---|---|---|---|---|---|---|---|---|
| Content | 0.44 | 0.22 | 0.07 | 420.95 | 0.00 | 0.22 | 0.01 | 0.00 |
| ppm | | | | | | | | |
| Elements | Cu | Li | Mn | Ni | Pb | Sn | Sr | Zn |
| Content | 81.55 | 1.49 | 1.40 | 2.34 | 0.32 | 0.00 | 13.69 | 0.27 |
| ppm | | | | | | | | |

It appears that the liquid phase contains very few metal elements, in particular very little Ag and Cu. Almost all of the metals are thus recovered in the solid phase of the treatment by supercritical water. The chemical analysis of the fraction of fines obtained after crushing (FIG. 8) also reveals an absence of copper. The process presented therefore makes it possible to recover almost all of the copper in a solid phase, which may subsequently be treated by hydrometallurgy. Advantageously, the solid phase may, prior to the hydrometallurgical treatment, be subjected to magnetic separation in order to eliminate the ferrous particles

1. A process for separating metals from electronic boards, characterized in that it comprises:
a) a step of treating electronic boards in an aqueous medium under supercritical conditions of said medium and
b) a subsequent step of crushing the materials in the solid state that are derived from the step of treating under supercritical conditions.

2. The separation process as claimed in claim 1, wherein, in step a), the electronic boards are not fragmented.

3. The separation process as claimed in claim 1, wherein the electronic boards are subjected to a fragmentation step prior to the treatment under supercritical conditions and are reduced to fragments having a size greater than or equal to 1 cm and less than or equal to 5 cm.

4. The separation process as claimed in claim 1, wherein said medium contains oxygen or one or more oxygen-generating species.

5. The separation process as claimed in claim 1, wherein the temperature and pressure conditions applied to the medium range from 374° C. to 600° C. and from 22.1 MPa to 30 MPa.

6. The separation process as claimed in claim 1, wherein said supercritical conditions of the aqueous medium are maintained for a duration greater than or equal to 30 minutes.

7. The separation process as claimed in claim 1, wherein, for the step of treating under supercritical conditions, the temperature is above 500° C.

8. The separation process as claimed in claim 1, wherein the crushed materials are treated so as to separate the fragments having a size of less than 2 mm.

9. The separation process as claimed in claim 1, wherein step a) is carried out in an autoclave and the supercritical conditions are achieved by increasing the temperature.

10. The separation process as claimed in claim 1, wherein the crushed materials are subjected to a low-intensity magnetic separation.

11. (canceled)

12. The separation process as claimed in claim 4, wherein said medium contains hydrogen peroxide.

13. The separation process as claimed in claim 6, wherein said supercritical conditions of the aqueous medium are maintained for a duration ranging from 60 minutes to 180 minutes.

14. The separation process as claimed in claim 7, wherein, for the step of treating under supercritical conditions, the temperature is about 600 ° C.

15. The separation process as claimed in claim 10, wherein the crushed materials are subjected to a low-intensity magnetic separation under a magnetic field of 400 gauss.

16. An electronic board prepared by the process of claim 1.

17. A process for separating metals from electronic boards, characterized in that it comprises:
a) fragmenting an electronic board into fragments having a size less than or equal to 5 cm;
b) treating the fragmented boards in an aqueous medium under supercritical conditions of said medium to a temperature of 374° C. to 600° C. and from 22.1 MPa to 30 MPa in an autoclave;
c) crushing in the solid state the treated materials derived from the step of treating under supercritical conditions; and
d) subjecting the crushed material to a low-intensity magnetic separation.

18. The process of claim 17, wherein the crushed materials are separated into fragments having a size of less than 2 mm.

19. The process of claim 17, wherein the fragments obtained in the step of fragmenting have a size greater than or equal to 1 cm.

20. The process of claim 17, wherein said aqueous medium contains oxygen or one or more oxygen-generating species.

21. The process of claim 17, wherein said low-intensity magnetic separation involves subjecting the crushed material to a magnetic field of 400 gauss.
